(19) United States
(12) Patent Application Publication
(10) Pub. No.: US 2005/0199898 A1
(43) Pub. Date: Sep. 15, 2005

(54) Light-emitting diode with micro-lens layer

(76) Inventors: Ming-Der Lin, Hsinchu (TW); San Bao Lin, Jungli City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/019,170

(22) Filed: Dec. 23, 2004

(30) Foreign Application Priority Data
Mar. 12, 2004 (TW) 093106605

(51) Int. Cl. H01L 29/22

(52) U.S. Cl. 257/98

(57) ABSTRACT

A light-emitting diode with a micro-lens layer, includes a die substrate, a second epitaxy layer deposited on the top surface of the die substrate, a first epitaxy layer deposited on a portion of the top surface of the second epitaxy layer, a second electrode formed on a portion of the top surface of the second epitaxy layer, a first electrode formed on a portion of the top surface of the first epitaxy layer, and a micro-lens layer mounted on a portion of the top surface of the first epitaxy layer. The micro-lens layer can change the projection angle and the projection path of the light beams radiated within the light-emitting diode in virtue of the diffusion effect caused by the micro-lens, and thereby improving the light-drawing efficiency and the luminance of the light-emitting diode.

### FIELD OF THE INVENTION

The present invention is related to a light-emitting diode, and more particularly to a light-emitting diode with a micro-lens layer for allowing the light beams radiated within the light-emitting diode to change their projection angle and projection path by the diffusion effect caused by the micro-lens.

### BACKGROUND OF THE INVENTION

As is well known in the prior art, a light-emitting diode has been widely employed in computer peripherals, communication products, and other electronic device because of its light weight, low power consumption, and prolonged longevity.

A conventional light-emitting diode is depicted in FIG. 1. As shown in FIG. 1, the light-emitting diode 10 includes a die substrate 11, a second epitaxy layer 13 deposited on the top surface of the die substrate 11, a first epitaxy layer 15 deposited on a portion of the top surface of the second epitaxy layer 13, a second electrode 17 formed on the other portion of the top surface of the second epitaxy layer 13, and a first electrode 19 formed on a portion of the top surface of the first epitaxy layer 15. When the first electrode 19 and the second electrode 17 are connected to a forward-biased power source, the light-emitting active region 135 of the light-emitting diode 10 can radiate light beams 121,123,125,127 accordingly.

In general, the refractive index n of the light-emitting diode 10 is larger than the refractive index nₐ of the atmosphere outside the light-emitting diode 10. To give an example, a light-emitting diode 10, which is made up of gallium nitride with other elements doped therein is taken as an illustration. The refractive index n of the gallium nitride is −2.4 and the refractive index nₐ of the outside atmosphere is 1, so that the critical angle for the light beam going from the light-emitting diode 10 to the outside atmosphere is about −25°. Therefore, as long as the projection angle of the light beam radiated from the light-emitting active region 135 of the light-emitting diode 10 with respect to the outside atmosphere is greater than the critical angle, the light beam is not possible to enter the outside atmosphere because of the total reflection effect. This would further result in a low light-drawing efficiency and a degradation of the luminance for the light-emitting diode. For example, the light beam 123 radiated from the light-emitting active region 135 of the light-emitting diode 10 has a projection angle which is smaller than the critical angle with respect to a first surface 101 located between the die substrate 11 and the outside atmosphere, and thus it can penetrate through the light-emitting diode 10 and project to the outside of the light-emitting diode 10. The light beam 127 has a projection angle which is smaller than the critical angle with respect to a third surface 103 located between the light-emitting diode 10 and the outside atmosphere, and thus it can also penetrate through the light-emitting diode 10 and project to the outside of the light-emitting diode 10. However, both of the light beams 121 and 125 have a projection angle which is larger than the critical angle with respect to the first surface 101, the second surface 102, the third surface 103, and the fourth surface 104, and thus the light beams 121 and 125 have to undergo numerous total internal reflection but can not penetrate through the light-emitting diode 10 and project to the outside of the light-emitting diode 10. This would result in a deficiency of light-drawing efficiency in the light-emitting diode 10. According to the teachings disclosed in the prior art references, if the light beams which can not project to the outside of the light-emitting diode 10 as a result of the total internal reflection can be drawn out of the light-emitting diode 10 in their entirety, the luminance of the light-emitting diode 10 can be increased by ten percents at least.

### SUMMARY OF THE INVENTION

Thus, it is a keynote of the present invention to devise a novel light-emitting diode capable of improving its light-drawing efficiency and enhancing its luminance to remove the drawbacks encountered by the prior art.

A primary object of the present invention is to provide a light-emitting diode with a micro-lens layer which includes a plurality of micro-lens mounted on the top surface of the first epitaxy layer of the light-emitting diode, and is capable of changing the projection angle of the light beams radiated within the light-emitting diode to be smaller than the critical angle by the diffusion effect caused by the micro-lens layer. Accordingly, the light-drawing efficiency and the luminance of the light-emitting diode can be improved.

A secondary object of the present invention is to provide a light-emitting diode with a micro-lens layer, which is coated with a reflective layer to increase the reflective index of the light beams radiated within the light-emitting diode.

Another object of the present invention is to provide a light-emitting diode with a micro-lens layer that can allow the light beams radiated within the light-emitting diode to project omnidirecionally from the light-emitting die of the light-emitting diode, so as to broaden the projection angle of the light beams.

To attain the foregoing objects, the present invention provides a light-emitting diode with a micro-lens layer, which includes a die substrate; a second epitaxy layer deposited on the top surface of the die substrate; at least one first epitaxy layer deposited a portion of the top surface of the second epitaxy layer; at least one first electrode fixedly formed on a portion of the top surface of the first epitaxy layer; at least one second fixedly formed on the other portion of the top surface of the second epitaxy layer; and a micro-lens layer formed on the other portion of the top surface of the first epitaxy layer for changing the projection angle or projection path of the light beams radiated within the light-emitting diode by the diffusion effect caused by the micro-lens layer.

Now the foregoing and other features and advantages of the present invention will be best understood through the following descriptions with reference to the accompanying drawings, wherein:

### BRIEF DESCRIPTION OF THE DRAWINGS

FIG. 1. depicts a light-emitting diode according to the prior art;

FIG. 2 depicts a light-emitting diode according to a preferred embodiment of the present invention;

FIG. 3 depicts a light-emitting diode according to another embodiment of the present invention;

FIG. 4 depicts a light-emitting diode according to yet another embodiment of the present invention;

FIG. 5 depicts a light-emitting diode according to yet another embodiment of the present invention; and

FIG. 6 depicts a light-emitting diode according to yet another embodiment of the present invention.

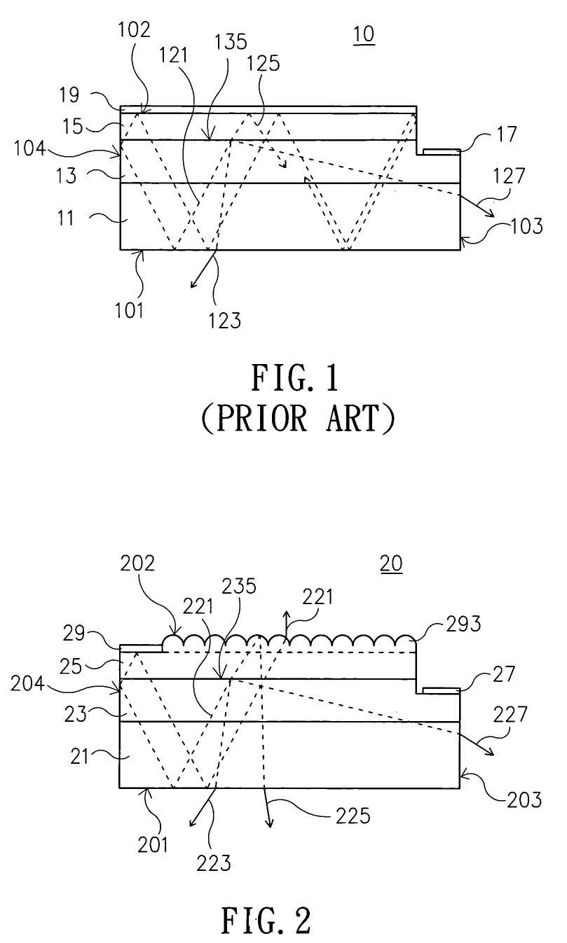

### DETAILED DESCRIPTION OF THE PREFERRED EMBODIMENT

Referring to FIG. 2, a light-emitting diode according to a preferred embodiment of the present invention is depicted. As shown, the light-emitting diode 20 with a micro-lens layer according to the present invention includes: a die substrate 21, a second epitaxy layer 23 deposited on the top surface of the die substrate 21, at least one first epitaxy layer 25 deposited on a portion of the top surface of the second epitaxy layer 23 with a light-emitting active region formed between the first epitaxy layer 25 and the second epitaxy layer 23, a second electrode 27 formed on a portion of the top surface of the second epitaxy layer 23, at least one first electrode 29 formed on a portion of the top surface of the first epitaxy layer 25, and a micro-lens layer 293 consisted of a plurality of micro-lens and formed on a portion the top surface of the first epitaxy layer 25.

In the present embodiment, the micro-lens layer 293 has a curvature which is constituted by a plurality of protuberances having a curve surface, and therefore the projection angle and the projection path of the light beams radiated within the light-emitting diode 20 can be changed, and the micro-lens layer 293 can provide a diffusion effect on the projective light beams accordingly. When the light beams undergo numerous reflection on the first surface 201 (the bottom surface of the light-emitting diode 20), the micro-lens layer 293 and the side surfaces 203,204, the light beams can penetrate through the light-emitting diode 20 and project to the outside of the light-emitting diode 20 as long as one of the projection angles with respect to the first surface 201, the micro-lens layer 293 and the side surfaces 203,204, is smaller than the critical angle. For example, when the light beam 223 which is radiated from the light-emitting active region 235 and projects to the first surface 201 has a smaller projection angle than the critical angle, the light beam 223 can project to the outside of the light-emitting diode 20 from the first surface 201. Also, when the light beam 227 projecting to the side surface 203 has a smaller projection angle with respect to the side surface 203 than the critical angle, the light beam 227 can penetrate through the light-emitting diode 20 from the side surface 203. However, when a light beam 221 which is radiated from the light-emitting active region 235 and projects to the bottom surface 201 has a larger projection angle than the critical angle, the light beam 221 is bound to undergo numerous total internal reflection on the micro-lens layer 293, the first surface 201, and the side surfaces 203 and 204. When the light beam 221 projects to the micro-lens layer 293, its projection angle and projection path can be changed by the diffusion effect caused by the micro-lens layer 293. When the light beam 221 has a smaller projection angle with respect to the micro-lens layer 293 than the critical angle, the light beam 221 can project to the outside from the micro-lens layer 293. In addition, the light beam 225 can change its projection angle and projection path by the diffusion effect caused by the micro-lens layer 293 to change its projection angle with respect to the bottom surface 201 to be smaller than the critical angle, such that the light beam 225 can penetrate through the light-emitting diode 20 from the first surface 201 without undergoing numerous total internal reflection within the light-emitting diode 20. By the incorporation of the micro-lens layer 293, both of the light beams 221 and 225 which have a larger projection angle than the critical angle can change their projection angle and projection path by the diffusion effect caused by the micro-lens layer 293, and further project to the outside of the light-emitting diode 20. In this way, the flaws persisting in the prior art that the light beams (121,125) having a larger projection angle than the critical angle can not be drawn to the outside of the light-emitting diode (10) can be thoroughly overcome.

From the above descriptions, it is readily known that the micro-lens layer 293 is provided with two capabilities: firstly, the micro-lens layer 293 has a curvature for changing the projection angle of the light beams 221 and 225, and thereby providing a diffusion effect; and secondly, The micro-lens layer 293 has a curvature for changing the normal vector of the second surface 202 (the top surface of the light-emitting diode 20), and thereby increasing the probability of allowing the light beam 221 to penetrate through the light-emitting diode 20. Consequently, the light-drawing efficiency and the luminance of the light-emitting diode can be improved.

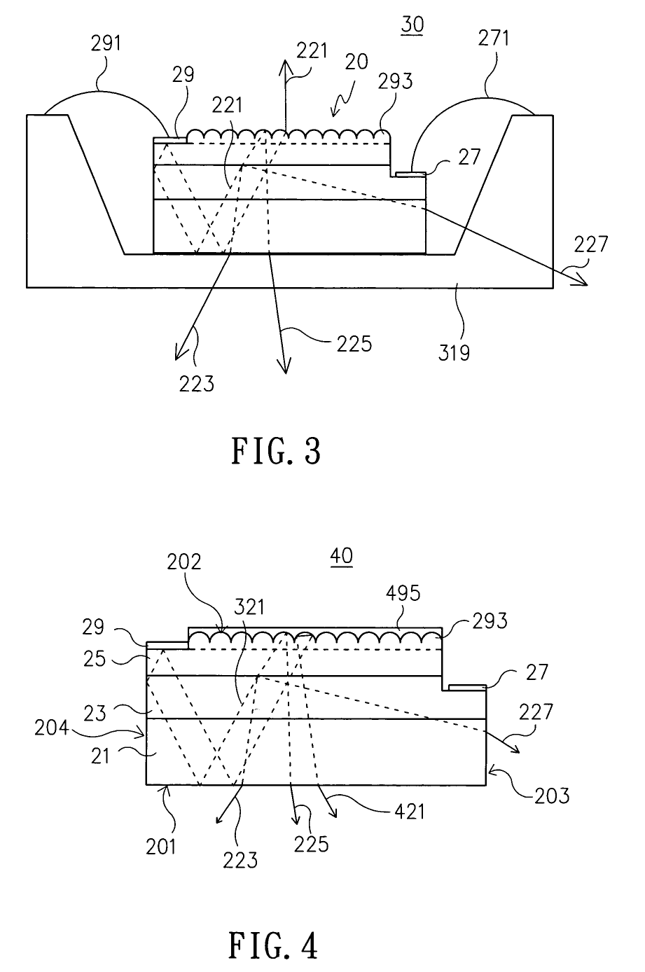

Next, referring to FIG. 3, a light-emitting diode according to another embodiment of the present invention is depicted. As shown, the light-emitting diode 20 of FIG. 2 is mounted on a transparent substrate 319, and the first electrode 29 and the second electrode 27 of the light-emitting diode are wired by a first lead 291 and a second lead 271, respectively. In this way, the light-emitting diode 30 of FIG. 3 not only has an excellent light-drawing efficiency, but is capable of achieving an omnidirectinoal illumination and the easiness of installation. Advantageously, the light-emitting diode according to the present invention can be broadly applicable to tubal lights or 3-D advertising boards.

Referring to FIG. 4, a light-emitting diode according to yet another embodiment of the present invention is depicted. As shown, the structure of the light-emitting diode of FIG. 4 is similar to the structure of the light-emitting diode of FIG. 2. However, the micro-lens layer 293 further includes a reflective layer 495, which is coated onto the second surface 202 of the micro-lens layer 293. When the light beam 421 within the light-emitting diode 40 projects onto the micro-lens layer 293, the light beam 421 can not penetrate through the light-emitting diode 40 from the second surface 202 but undergo a plurality of internal reflection on the first surface 201, the micro-lens layer 293, and the side surfaces 203 and 204 to change its projection angle, and finally penetrate through the light-emitting diode 40 from the first surface 201. Through the incorporation of the reflective layer 495, the direction of protection of the light beams toward the outside of the light-emitting diode 40 is limited to the direction toward the first surface 201 or the direction toward the side surface 203 and 204, so as to enhance the luminance of the light-emitting diode 40 in a certain direction or the luminance of the light-emitting diode 40 within a certain range.

Although the micro-lens layer 293 and the first epitaxy layer 25 are separated as shown in the drawings, both of them can be made up of the same material. For example, the first epitaxy layer 25 may be manipulated by laser processing or by lithography and etching process to form a micro-lens layer 293 on its surface. The micro-lens layer 293 can be an insulator, such as silicon dioxide (SiO₂), titanium dioxide (TiO₂), or silicon nitride (Si₃N₄), or otherwise the micro-lens can be a conductor, such as indium tin oxide (ITO). In case that the micro-lens layer 293 is a conductor, the micro-lens layer 293 is provide with the capability of electric conduction like the first electrode 29, and thereby promoting the uniform current distribution within the light-emitting diode.

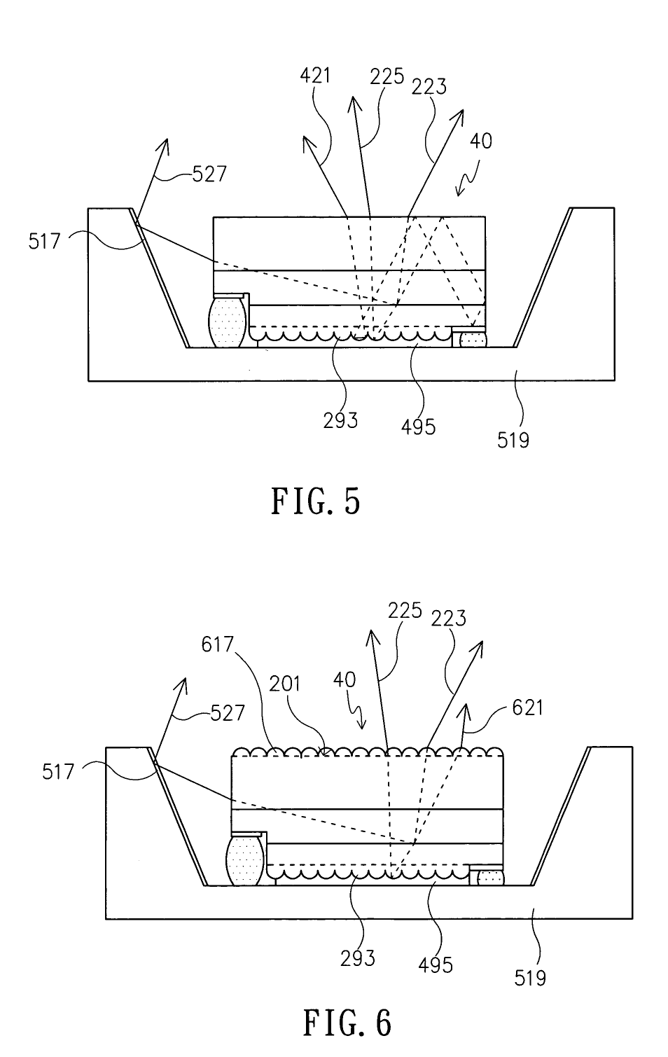

Referring to FIG. 5, a light-emitting diode according to yet another embodiment of the present invention is depicted. As shown, the light-emitting diode 40 of FIG. 4 is mounted on a carrier substrate 519 having a reflective layer 517 by flip-chip mounting. Therefore, the light beam 527 projected from the side surface of the light-emitting diode 40 can be guided to a specific location by the reflective layer 517 for projection, and thereby forcing the light beams to be projected toward a single direction.

At last, referring to FIG. 6, a light-emitting diode according to yet another embodiment of the present invention is depicted. As shown, the structure of the light-emitting diode of FIG. 6 is similar to the structure of the light-emitting diode of FIG. 5. However, the light-emitting diode of FIG. 6 further includes a second micro-lens layer 617 mounted on the first surface 201. In this configuration, the light beam 621 projecting onto the first surface 201 can penetrate through the light-emitting diode 40 from the first surface 201 by the change of the interfacial normal vector with respect to the second micro-lens layer 617, and thus reduce the number of times of the internal reflections underwent by the light beams within the light-emitting diode 40 and reduce the probability of allowing the light beams to be absorbed by the light-emitting diode 40.

In conclusion, the present invention is associated with a light-emitting diode, and more particularly with a light-emitting diode with a micro-lens layer, in which the light beams radiated within the light-emitting diode can change their projection angle and projection path by the diffusion effect caused by the micro-lens layer, such that the light-drawing efficiency and luminance of the light-emitting diode are enhanced.

While the present invention has been described in terms of what are presently considered to be the most practical and preferred embodiments, it is to be understood that the present invention need not be restricted to the disclosed embodiment. On the contrary, it is intended to cover various modifications and similar arrangements included within the spirit and scope of the appended claims, which are to be accorded with the broadest interpretation so as to encompass all such modifications and similar structures. Therefore, the above description and illustration should not be taken as limiting the scope of the present invention which is defined by the appended claims.

1. A light-emitting diode with a micro-lens layer, comprising:
a die substrate;
a second epitaxy layer deposited on the top surface of the die substrate;
at least one first epitaxy layer deposited on a portion of the top surface of the second epitaxy layer;
at least one first electrode fixedly formed on a portion of the top surface of the first epitaxy layer;
at least one second electrode fixedly formed on the other portion of the top surface of the second epitaxy layer; and
at least one micro-lens layer formed on the other portion of the top surface of the first epitaxy layer for allowing the light beams radiated within the light-emitting diode to change their projection angle or projection path by a diffusion effect caused by the micro-lens layer.

2. The light-emitting diode according to claim 1, wherein the top surface of the micro-lens layer is coated with a reflective layer.

3. The light-emitting diode according to claim 1, further comprising a carrier substrate for allowing the light-emitting diode to be fixedly mounted thereon.

4. The light-emitting diode according to claim 3, wherein the light-emitting diode is fixedly mounted on the carrier substrate by flip-chip mounting.

5. The light-emitting diode according to claim 1, wherein the micro-lens layer is formed by the same material as the first epitaxy layer.

6. The light-emitting diode according to claim 1, wherein the micro-lens layer is formed by a conductor or an insulator.

7. The light-emitting diode according to claim 6, wherein the micro-lens layer is formed by one or an alloy of a group of materials consisting of silicon dioxide, titanium dioxide, and silicon nitride.

8. The light-emitting diode according to claim 6, wherein the micro-lens layer is formed by indium tin oxide.

9. The light-emitting diode according to claim 1, further comprising a second micro-lens layer fixedly mounted on the bottom surface of a light-emitting die of the light-emitting diode.

10. The light-emitting diode according to claim 3, further comprising a reflective layer mounted on one side of the carrier substrate.

11. The light-emitting diode according to claim 6, wherein the micro-lens layer is constituted by a plurality of protuberances having a curve surface.
